(19) United States
(12) Patent Application Publication
(10) Pub. No.: US 2026/0290142 A1
(43) Pub. Date: Sep. 24, 2026

(54) DROWNING ALARM DEVICE

(71) Applicant: Feixue Liu, Shenzhen (CN)

(72) Inventor: Feixue Liu, Shenzhen (CN)

(21) Appl. No.: 19/671,479

(22) Filed: May 8, 2026

(51) Int. Cl. G08B 21/08; H05K 5/06

(52) U.S. Cl. CPC G08B 21/084; H05K 5/061

(57) ABSTRACT

A drowning alarm device is provided, including: a housing which is overall configured as a sealed waterproof structure, wherein a floating cavity is formed inside the housing; a water contact sensor arranged at a bottom of the housing and configured to: monitor a water contact state and correspondingly generate a water contact signal; a drowning sensor arranged inside the housing and configured to: monitor a drowning state and correspondingly generate a drowning signal; and a control panel arranged inside the housing and configured to: generate a driving signal based on the water contact signal, control the drowning sensor to be activated, and receive the drowning signal. The drowning alarm device has a simple structure, accurate monitoring, and low power consumption.

### TECHNICAL FIELD

The present disclosure relates to the technical field of pool security systems, and more specifically, to a drowning alarm device.

### BACKGROUND

Swimming is an exercise beneficial for the physical health. More people choose to carry out swimming activities in swimming pools. There is a large number of beginners among swimmers, which raises significant safety protection requirements for the swimming pools. However, with upsizing of swimming pool construction, despite the presence of safety personnel, it remains difficult to keep constant watch over every swimmer at all times, which poses a safety risk for the beginners. Therefore, a drowning alarm device has emerged to automatically monitor and recognize drowning situations, to avoid safety accidents.

The existing drowning alarm device has more or less defects. For example, buoyancy is implemented by usually using a closed air bladder structure, so that the structure is complex. Alternatively, water ripples are detected via metal contact points, so that the accuracy is low, false alarms will be sounded, and possible water contamination can be caused by the metal contact points. Alternatively, monitoring the water ripples in real time through a sensor has high power consumption, so that it is difficult to use the device for long time. The overall design is inconvenient to use and difficultly meets users' needs. Therefore, it is necessary to provide an improved technical solution.

### SUMMARY

In view of the above contents, the present disclosure aims to at least solve one of the technical problems in the prior art. To this end, the present disclosure provides a drowning alarm device. A water contact sensor monitors a water contact signal, thus controlling and activating drowning monitoring of a drowning sensor. Drowning is monitored by indirectly monitoring water ripples. Furthermore, the drowning monitoring is activated only when the alarm device is in a water contact state, so that a monitoring error is avoided, and the monitoring accuracy is enhanced. The device has a simple structure and convenient operation.

To this end, in a first aspect, an embodiment of the present disclosure provides a drowning alarm device, including:
a housing which is overall configured as a sealed waterproof structure, where a floating cavity is formed inside the housing;
a water contact sensor arranged at a bottom of the housing and configured to: monitor a water contact state and correspondingly generate a water contact signal;
a drowning sensor arranged inside the housing and configured to: monitor a drowning state and correspondingly generate a drowning signal; and
a control panel arranged inside the housing and configured to: generate a driving signal based on the water contact signal, control the drowning sensor to be activated, and receive the drowning signal.

Preferably, the housing includes a lower shell and an upper shell assembly. The upper shell assembly is hermetically connected to an upper edge of the lower shell. The upper shell assembly and the lower shell enclose the floating cavity. The water contact sensor is arranged at a bottom of the lower shell. The drowning sensor and the control panel are arranged on the upper shell assembly.

Preferably, the lower shell includes a bottom plate and a side plate which obliquely extends outward and upward from an outer edge of the bottom plate. The upper shell assembly is hermetically connected to an upper edge of the side plate. The water contact sensor is arranged on the bottom plate.

Preferably, a convex structure is arranged at the upper edge of the side plate. The upper shell assembly is provided with a concave structure for correspondingly receiving the convex structure. An ultrasonically molten waterproof connecting strip is arranged between the convex structure and the concave structure.

Preferably, the upper shell assembly includes an upper shell adapted to the lower shell and a top cover adapted to the upper shell. A mounting cavity is formed between the upper shell and the top cover. The drowning sensor and the control panel are arranged in the mounting cavity.

Preferably, a size of the top cover is less than a size of the lower shell. The upper shell includes a side wall adapted to the top cover, a cover plate which obliquely extends outward and downward from a lower edge of the side wall, and a mounting plate which extends downward and inward from the side wall. An outer edge of the cover plate is adapted to the upper edge of the lower shell; the lower shell, the cover plate, the side wall, and the mounting plate enclose the floating cavity. The mounting cavity is formed in an upper side of the mounting plate.

Preferably, an upper edge of the side wall is connected to an upper edge of the mounting plate. The upper shell further includes a connecting wall which extends upward from a position of connection between the side wall and the mounting plate. The top cover is detachably adaptively connected to the connecting wall.

Preferably, the connecting wall is provided with an outward connecting slot. The top cover is capable of covering the connecting slot from an outer side. The upper shell assembly further includes a waterproof ring received within the connecting slot and is hermetically connected between the connecting wall and the top cover.

Preferably, the drowning sensor is arranged on the inner side of the top cover; and/or,
the control panel is arranged on the inner side of the top cover; and/or,
a power supply assembly is further included, which is arranged on the upper shell and is located in the mounting cavity.

Preferably, the water contact sensor is configured as one of a capacitive sensor, an ultrasonic sensor, and a photoelectric sensor; and/or, the drowning sensor is configured as one of an accelerometer sensor, a gyroscope sensor, and a vibration sensor.

According to the drowning alarm device provided in the present disclosure, in one aspect, monitoring with a single sensor is improved into a combination of water contact monitoring and drowning monitoring, so that the problem of low detection accuracy caused by direct detection of water ripples is avoided. In addition, when the device is not in the water contact state, the drowning sensor and the control panel are kept in a low-power state. When the device is in the water contact state, the control panel and the drowning sensor have officially entered a detection mode to precisely recognize drowning. The drowning alarm device has a simple structure, perfect functions, and low power consumption, and can provide a good user experience.

### BRIEF DESCRIPTION OF THE DRAWINGS

FIG. 1 is a schematic diagram of a three-dimensional structure of a drowning alarm device provided in an embodiment of the present disclosure;

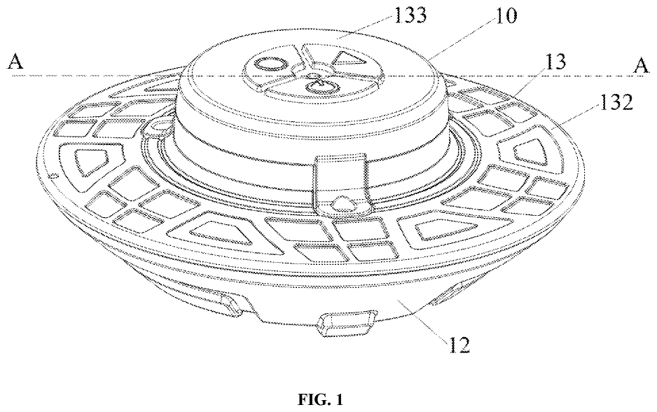

FIG. 2 is an exploded diagram of a structure of the drowning alarm device in FIG. 1;

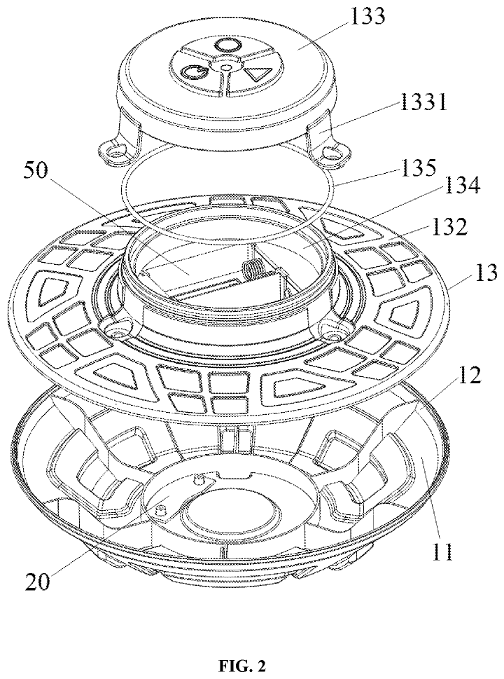

FIG. 3 is a schematic diagram of a three-dimensional structure of a top cover in the drowning alarm device in FIG. 2 in another viewing angle; and

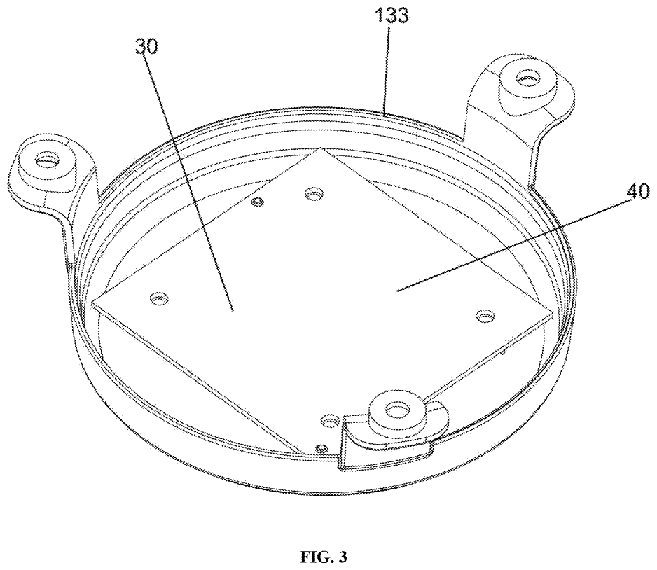

FIG. 4 is a cross-sectional view of the drowning alarm device in FIG. 1 along line A-A.

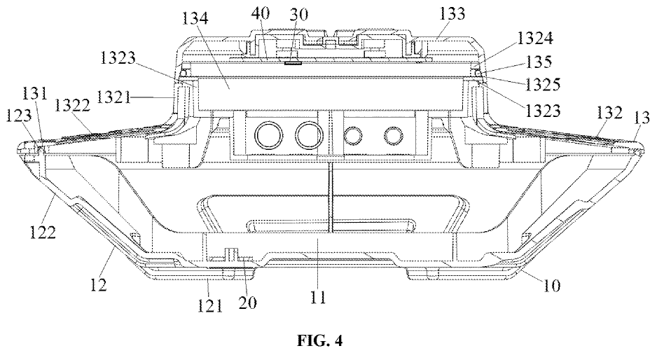

### DETAILED DESCRIPTION OF THE EMBODIMENTS

The embodiments of the present disclosure are described in detail below, and examples of the embodiments are shown in accompanying drawings, where the same or similar elements or the elements having same or similar functions are denoted by the same or similar reference numerals throughout the description. The embodiments described below with reference to the accompanying drawings are exemplary, aim to explain the present disclosure, and should not be construed as a limitation on the present disclosure.

The following disclosure provides many different embodiments or examples to implement different structures of the present disclosure. In order to simplify the disclosure of the present disclosure, components and settings of specific examples are described below. Certainly, they are merely examples and are not intended to limit the present disclosure. In addition, the present disclosure may repeatedly refer to numbers and/or letters in different examples. Such repetition is for purposes of simplicity and clarity and does not itself indicate a relationship between the various embodiments and/or settings discussed. In addition, the present disclosure provides examples of various specific processes and materials, but a person of ordinary skill in the art will recognize the application of other processes and/or the use of other materials.

The present disclosure provides a drowning alarm device which is mainly applied to safety protection of a swimming pool and is specifically configured to automatically monitor a drowning event in a swimming pool. It is particularly necessary when there are a large number of swimmers, and serves as an effective supplement to manual safety monitoring.

The drowning alarm device specifically includes:
a housing 10 which is overall configured as a sealed waterproof structure, where a floating cavity 11 is formed inside the housing;
a water contact sensor 20 arranged at a bottom of the housing 10 and configured to: monitor a water contact state and correspondingly generate a water contact signal;
a drowning sensor 30 arranged inside the housing 10 and configured to: monitor a drowning state and correspondingly generate a drowning signal; and
a control panel 40 arranged inside the housing 10 and configured to: generate a driving signal based on the water contact signal, control the drowning sensor 30 to be activated, and receive the drowning signal.

The floating cavity 11 is configured to keep the entire drowning alarm device floating on a water surface of a swimming pool. In addition, a shape of the housing 10 is designed to keep floating on a water surface of a swimming pool relatively stably in a normal state. Correspondingly, a bottom that is directly in contact with the water surface and a top that remains floating on the water surface are formed. No object the drowning alarm device is placed into the swimming pool in any state, its static floating state remains consistent with the above description. Therefore, the water contact sensor 20 arranged at the bottom can accurately monitor a water contact state of the drowning alarm device. The water contact sensor 20 generates a water contact signal and is electrically connected to the control panel 40. The drowning sensor 30 is electrically connected to the control panel 40. The water contact signal is transmitted to the control panel 40, and the control panel 40 generates a driving signal to control the drowning sensor 30 to be activated based on the water contact signal, thus activating drowning monitoring. When drowning is detected, the drowning sensor 30 generates a corresponding drowning signal and transmits it to the control panel 40. The control panel 40 can correspondingly generate an alarm signal, to trigger an audible and visual alert through its built-in alarm or transmit an alarm signal to the outside via communication connection. Real-time alarms are sent to safety personnel, administrators, or a management platform to prevent the occurrence of safety accidents.

Specifically, the housing 10 includes a lower shell 12 and an upper shell assembly 13. The upper shell assembly 13 is hermetically connected to an upper edge of the lower shell 12. The upper shell assembly 13 and the lower shell 12 enclose the floating cavity 11. The water contact sensor 30 is arranged at a bottom of the lower shell 12. The drowning sensor 30 and the control panel 40 are arranged on the upper shell assembly 13. In this embodiment, the housing 10 is configured as a split structure formed by combining the lower shell 12 with the upper shell assembly 13, thus facilitating modular manufacturing and assembly. It can be understood that in other embodiments, the housing 10 can also be configured as an integrated structure with the floating cavity 11, which can similarly achieve the aforementioned technical effects.

Further, the lower shell 12 includes a bottom plate 121 and a side plate 122 which obliquely extends outward and upward from an outer edge of the bottom plate 121. The upper shell assembly 13 is hermetically connected to an upper edge of the side plate 122. The water contact sensor 30 is arranged on the bottom plate 121. In this embodiment, the lower shell 12 is specifically configured as the bottom plate 121 and the side plate 122 which obliquely extends, so that the overall lower shell 12 is formed into a shape similar to a hull. It is convenient to keep the housing 10 in a stable floating posture in the swimming pool. It can be understood that the specific structure of the lower shell 12 is not limited to this. Even the overall center of gravity is offset toward the bottom, the housing 10 can also keep a stable water contact state.

Further, a convex structure 123 is arranged at the upper edge of the side plate 122. The upper shell assembly 13 is provided with a concave structure 131 for correspondingly receiving the convex structure 123. An ultrasonically molten waterproof connecting strip (not shown) is arranged between the convex structure 123 and the concave structure 131. In this embodiment, a sealed and waterproof connection is implemented by using mutually non-interfering convex and concave structures and the ultrasonically molten waterproof connecting strip, thus ensuring structural stability. It can be understood that this connection structure is not limited to this. It can also be achieved through adhesive sealing or designed as a detachable and assemblable sealing structure, such as a sealing ring, to implement removal, mounting, and maintenance.

Furthermore, the upper shell assembly 13 includes an upper shell 132 adapted to the lower shell 12 and a top cover 133 adapted to the upper shell 132. A mounting cavity 134 is formed between the upper shell 132 and the top cover 133. The drowning sensor 30 and the control panel 40 are arranged in the mounting cavity 134. In this embodiment, the upper shell assembly 13 is configured as a detachable split structure with the mounting cavity 134. The mounting cavity 134 is independent of the floating cavity 11. The drowning sensor 30 is arranged in the mounting cavity 134, to facilitate mounting, removal, and maintenance. In addition, the top cover 133 is provided with a button switch (not shown in the figure), which is electrically connected to the control panel 40.

Further, a size of the top cover 133 is less than a size of the lower shell 12. The upper shell 132 includes a side wall 1321 adapted to the top cover 133, a cover plate 1322 which obliquely extends outward and downward from a lower edge of the side wall 1321, and a mounting plate 1323 which extends downward and inward from the side wall 1321. An outer edge of the cover plate 1322 is adapted to the upper edge of the lower shell 12. The lower shell 12, the cover plate 1322, the side wall 1321, and the mounting plate 1323 enclose the floating cavity 11. The mounting cavity 134 is formed in an upper side of the mounting plate 1323. In this embodiment, the sizes of both the top cover 133 and an upper portion of the upper shell 132 are less than the size of the lower shell 12, so that the overall center of gravity of the housing 10 is offset and closer to the bottom, thereby ensuring that the housing 10 remains stable in the water contact state.

Further, an upper edge of the side wall 1321 is connected to an upper edge of the mounting plate 1323. The upper shell 132 further includes a connecting wall 1324 which extends upward from a position of connection between the side wall 1321 and the mounting plate 1323. The top cover 133 is detachably adaptively connected to the connecting wall 1324.

Furthermore, the connecting wall 1324 is provided with an outward connecting slot 1325. The top cover 133 is capable of covering the connecting slot 1325 from an outer side. The upper shell assembly 13 further includes a waterproof ring 135 received within the connecting slot 1325 and is hermetically connected between the connecting wall 1324 and the top cover 133.

Further, the drowning sensor 30 is arranged on the inner side of the top cover 133. Specifically, the top cover 133 is further provided with connecting lugs 1331 which are locked to the upper shell 132 through locking components (not shown in the figure). The drowning sensor 30 is arranged on the top cover 133, to facilitate removal and mounting of the top cover 133 for maintenance of the drowning sensor 30.

Further, the control panel 40 is arranged on the inner side of the top cover 133. In this way, it also facilitates the removal, mounting, and maintenance of the control panel 40. Specifically, the drowning sensor 30 can be arranged on the control panel 40, or they can be separately disposed, as long as the drowning sensor 30 is electrically connected to the control panel 40.

Further, the drowning alarm device further includes a power supply assembly 50 arranged on the upper shell 132 and located in the mounting cavity 134. In this embodiment, the power supply assembly 50 is arranged inside the mounting cavity 134. Specifically, the power supply assembly 50 is configured as a battery compartment that is electrically connected to the control panel 40. The battery compartment can accommodate a conventional battery, such as a 1# battery, a #2 battery, a 5# battery, or a 7# battery.

Further, the water contact sensor 20 is configured as one of a capacitive sensor, an ultrasonic sensor, and a photoelectric sensor. Specifically, the water contact sensor 20 is arranged inside the floating cavity 11 as a non-contact sensor to avoid direct contact with water or damage to the sensor or water quality. The water contact sensor 20 specifically detects changes in capacitance, ultrasonic induction, or photoelectric parameters when approaching water, so as to recognize a water contact state. In a preferred embodiment, the water contact sensor 20 is configured as a capacitive sensor.

Further, the drowning sensor 20 is configured as one of an accelerometer sensor, a gyroscope sensor, and a vibration sensor. The drowning sensor 20 is specifically configured to monitor changes in acceleration, angle, and vibration of the device, so as to recognize significant movements of the drowning alarm device in water. In a preferred embodiment, the drowning sensor 30 is configured as a gyroscope sensor.

The drowning alarm device provided in the present disclosure is specifically an integrated closed structure with an IP67 waterproof structure. A magnitude of water ripples based on can be determined based on a posture of a gyroscope on the control panel 40. Alternatively, since ripples generated by other foreign matters falling into water have different sizes, a weight of a fallen object is determined by an algorithm based on angle information generated by the water ripples, so as to filter out non-alarm events and reduce false alarms. By using non-contact water contact detection, drowning monitoring work can be carried out by monitoring the water contact state without being in contact with water. The device enters a low-power mode by means of dormancy. The drowning monitoring work is carried out when a fallen object has been detected, and the standby duration can exceed 100 days.

A working principle of the drowning alarm device provided in the present disclosure is as follows: A battery is put into the device, and then the device is turned on and put into water. The water contact sensor 20 detects surrounding media to generate different capacitance values for the water, and transmits a water contact signal to the control panel 40. The control panel 40 receives the water contact signal and starts to work. The drowning sensor 30 generates an angle value.

When a foreign object falls into the water, water ripples will be formed on the water surface, and the housing 10 will sway along with the ripples. The drowning sensor 30 in the control panel 40 can generate a varying angle value. When the water ripples are large, the drowning sensor 30 can generate a large continuous varying angle value. When the water ripples are small, the drowning sensor can generate a small continuous varying angle value. Whether it is a heavy or light object falling is determined through a varying law and amplitude of the angle, so that the number of false alarms can be effectively reduced.

When the water surface tends to be calm for a period of time, the control panel 40 enters a low-power dormancy state. The control panel can only be awakened when the angle of the drowning sensor 30 changes. This greatly reduces the power consumption.

According to the drowning alarm device provided in the present disclosure, in one aspect, monitoring with a single sensor is improved into a combination of water contact monitoring and drowning monitoring, so that the problem of low detection accuracy caused by direct detection of water ripples is avoided. In addition, when the device is not in the water contact state, the drowning sensor 30 and the control panel 40 are kept in a low-power state. When the device is in the water contact state, the control panel 40 and the drowning sensor 30 have officially entered a detection mode to precisely recognize drowning. The drowning alarm device has a simple structure, perfect functions, and low power consumption, and can provide a good user experience.

In the description of this specification, the description referring to the terms “an embodiment”, “some embodiments”, “example”, “specific examples”, “some examples”, or the like means that specific features, structures, materials or characteristics described in connection with the embodiments or examples are included in at least one embodiment or example of the present disclosure. In this specification, the schematic representations of the above terms are not necessarily intended to refer to the same embodiment or example. Furthermore, the specific features, structures, materials or characteristics described may be combined in any suitable manner in any one or more embodiments or examples. In addition, those skilled in the art may combine the different embodiments or examples described in this specification, as well as the features of different embodiments or examples, without mutual contradictions.

Although the embodiments of the present disclosure have been shown and described, it can be understood by those of ordinary skill in the art that various changes, modifications, substitutions, and variations can be made to these embodiments without departing from the principle and purpose of the present disclosure. The scope of the present disclosure is defined by the claims and their equivalents.

What is claimed is:

1. A drowning alarm device, comprising:
a housing which is overall configured as a sealed waterproof structure, wherein a floating cavity is formed inside the housing;
a water contact sensor arranged at a bottom of the housing and configured to: monitor a water contact state and correspondingly generate a water contact signal;
a drowning sensor arranged inside the housing and configured to: monitor a drowning state and correspondingly generate a drowning signal; and
a control panel arranged inside the housing and configured to: generate a driving signal based on the water contact signal, control the drowning sensor to be activated, and receive the drowning signal.

2. The drowning alarm device according to claim 1, wherein the housing comprises a lower shell and an upper shell assembly; the upper shell assembly is hermetically connected to an upper edge of the lower shell; the upper shell assembly and the lower shell enclose the floating cavity; the water contact sensor is arranged at a bottom of the lower shell; and the drowning sensor and the control panel are arranged on the upper shell assembly.

3. The drowning alarm device according to claim 2, wherein the lower shell comprises a bottom plate and a side plate which obliquely extends outward and upward from an outer edge of the bottom plate; the upper shell assembly is hermetically connected to an upper edge of the side plate; and the water contact sensor is arranged on the bottom plate.

4. The drowning alarm device according to claim 3, wherein a convex structure is arranged at the upper edge of the side plate; the upper shell assembly is provided with a concave structure for correspondingly receiving the convex structure; and an ultrasonically molten waterproof connecting strip is arranged between the convex structure and the concave structure.

5. The drowning alarm device according to claim 2, wherein the upper shell assembly comprises an upper shell adapted to the lower shell and a top cover adapted to the upper shell; a mounting cavity is formed between the upper shell and the top cover; and the drowning sensor and the control panel are arranged in the mounting cavity.

6. The drowning alarm device according to claim 5, wherein a size of the top cover is less than a size of the lower shell; the upper shell comprises a side wall adapted to the top cover, a cover plate which obliquely extends outward and downward from a lower edge of the side wall, and a mounting plate which extends downward and inward from the side wall;
an outer edge of the cover plate is adapted to the upper edge of the lower shell; the lower shell, the cover plate, the side wall, and the mounting plate enclose the floating cavity; and
the mounting cavity is formed in an upper side of the mounting plate.

7. The drowning alarm device according to claim 6, wherein an upper edge of the side wall is connected to an upper edge of the mounting plate; the upper shell further comprises a connecting wall which extends upward from a position of connection between the side wall and the mounting plate; and the top cover is detachably adaptively connected to the connecting wall.

8. The drowning alarm device according to claim 7, wherein the connecting wall is provided with an outward connecting slot; the top cover is capable of covering the connecting slot from an outer side; the upper shell assembly further comprises a waterproof ring received within the connecting slot and is hermetically connected between the connecting wall and the top cover.

9. The drowning alarm device according to claim 5, wherein the drowning sensor is arranged on an inner side of the top cover; and/or,
the control panel is arranged on the inner side of the top cover; and/or,
a power supply assembly is further comprised, which is arranged on the upper shell and is located in the mounting cavity.

10. The drowning alarm device according to claim 1, wherein the water contact sensor is configured as one of a capacitive sensor, an ultrasonic sensor, and a photoelectric sensor; and/or,
the drowning sensor is configured as one of an accelerometer sensor, a gyroscope sensor, and a vibration sensor.
